(19) United States
(12) Patent Application Publication
(10) Pub. No.: US 2025/0164102 A1
(43) Pub. Date: May 22, 2025

(54) LIQUID MATERIAL VAPORIZATION APPARATUS AND OPERATION SETTING METHOD THEREOF

(71) Applicant: HORIBA STEC, Co., Ltd., Kyoto-shi (JP)

(72) Inventors: Hidenori Oba, Kyoto-shi (JP); Hajime Kawakado, Kyoto-shi (JP)

(21) Appl. No.: 18/950,461

(22) Filed: Nov. 18, 2024

(30) Foreign Application Priority Data
Nov. 22, 2023 (JP) 2023-198653

(51) Int. Cl. F22B 35/00; F22B 37/78; H01L 21/67

(52) U.S. Cl. CPC F22B 35/00; F22B 37/78; H01L 21/67017

(57) ABSTRACT

A liquid material vaporization apparatus operates such that, in a gas generation mode, a liquid material is supplied to a tank through a supply path via a first on-off valve set to a predetermined first opening degree, and operates such that, in a purge mode, a purge gas is introduced into the tank through the supply path via the first on-off valve set to a second opening degree that is larger than the first opening degree.

### BACKGROUND OF THE INVENTION

### Technical Field

The present invention relates to a liquid material vaporization apparatus that heats and vaporizes a liquid material, and an operation setting method thereof.

### Description of the Related Art

As disclosed in JP 2022-135920 A, a liquid material vaporization apparatus that generates a gas for use in a semiconductor manufacturing process or the like, by vaporizing a liquid material has conventionally been developed.

As illustrated in FIG. 2, such a liquid material vaporization apparatus includes: a tank 11; a supply path R11 through which a liquid material is supplied to the tank 11; a heater (attached to the tank 11 and not illustrated) that heats the liquid material in the tank 11; a gas delivery path R12 through which a vaporized gas generated from the liquid material by heat in the tank 11 is delivered; a flow rate controller 12 that performs FB control such that a flow rate of the vaporized gas flowing through the gas delivery path R12 is adjusted to a predetermined value; and a housing 13 that has a size not standardized but unified and accommodates or holds these components.

During the operation in a mode (gas generation mode) in which the vaporized gas is generated and supplied to an external device, an on-off valve V12 provided on the gas delivery path R12 is opened to guide the vaporized gas generated by heat from the heater, to a target device, such as a semiconductor process chamber, through the gas delivery path R12 while the flow rate is controlled by the flow rate controller 12.

A sensor 14 that detects the amount (liquid level) of the liquid material is provided in the tank 11. In the gas generation mode, when the amount of the liquid material in the tank 11 falls below a predetermined value due to the delivery of the vaporized gas, an on-off valve V11 for liquid material supply that is provided on the supply path R11 is opened to supply a liquid material to the tank 11. On the other hand, when the amount of the liquid material in the tank 11 exceeds the predetermined value due to the supply of the liquid material, the on-off valve V11 is closed to stop the supply of the liquid material. In this manner, the amount of the liquid material stored in the tank 11 is controlled to be constant while the vaporized gas is delivered at a constant flow rate controlled by the flow rate controller 12, in the gas generation mode.

FIG. 3 is a time-series graph showing a relationship, in the gas generation mode, between a delivery flow rate of the vaporized gas and a timing of supplying the liquid material to the tank 11 with the on-off valve V11.

This graph reveals that the delivery flow rate of the vaporized gas slightly fluctuates at the timing of supplying the liquid material. As one of the factors thereof, it is considered that the pressure and temperature in the tank 11 are changed due to the supply of the liquid material.

To restrain the changes in the temperature and pressure in the tank, which are one of the factors of fluctuations in the delivery flow rate of the vaporized gas, conventionally, the on-off valve V11 for liquid material supply has such a configuration that an opening degree in the open state is equal to or less than a certain value so as to prevent the liquid material from flowing into the tank 11 in large amounts at a time.

In a case where the liquid material and vaporized gas that have remained are purged from the inside of the tank 11 (purge mode) for removal of the liquid material vaporization apparatus or other reasons, a purge gas is introduced through the supply path R11 into the tank 11, and then is discharged through the gas delivery path R12 and the flow rate controller 12.

The supply path R11 is conventionally provided with a bypass path R14 on which an on-off valve V14 for purge gas discharge is provided. The purge gas is discharged via not only the on-off valve V11 for liquid material supply but also the on-off valve V14 for purge gas discharge by opening also the on-off valve V14. This configuration allows a purge gas to flow at a higher flow rate, and enables a purge in a short time with reliably.

In FIG. 2, reference numeral 15 denotes a preheater that preheats a liquid material immediately before the liquid material is supplied to the tank 11, and reference numeral 16 denotes a pressure sensor that measures the pressure in the tank 11.

### PRIOR ART DOCUMENT

### Patent Document

JP 2022-135920 A

### SUMMARY OF THE INVENTION

In the meantime, an increase in capacity of the tank is beneficial since a float sensor or the like having high operational reliability can be used for detecting the amount of the liquid material stored in the tank, for example.

However, since the size of the housing is defined to some extent as described above, it is difficult to simply increase the capacity of the tank in the conventional configuration. For example, if a simple measure such as omitting some of the components other than the tank is taken, a problem such as an increase in fluctuation range of the delivery flow rate of the vaporized gas may occur.

The present invention has been made in view of the above problem, and an object of the present invention is to provide a liquid material vaporization apparatus capable of increasing the capacity of a tank to enjoy the benefit therefrom while securing conventional performance.

That is, a liquid material vaporization apparatus of the present invention is as follows.

1

A liquid material vaporization apparatus including:

a tank;

a supply path through which a liquid material is supplied to the tank; and

a first on-off valve that is provided on the supply path,

the liquid material vaporization apparatus being configured to operate such that, in a gas generation mode, the liquid material is supplied to the tank through the supply path via the first on-off valve set to a predetermined first opening degree,

the liquid material vaporization apparatus being configured to operate such that, in a purge mode, a purge gas is introduced into the tank through the supply path via the first on-off valve set to a second opening degree that is larger than the first opening degree.

According to this configuration, the first on-off valve has two functions, that is, a function of a conventional on-off valve for liquid material supply and a function of a conventional on-off valve for purge gas discharge. It is therefore possible to reduce the number of parts and increase the capacity of the tank accordingly.

As a result, it is possible to improve the reliability of detecting the liquid level in the tank. For example, it is possible to use a float sensor as a liquid level sensor.

In addition, since the capacity of the tank is increased, the liquid material can be stored in large amounts in the tank. Therefore, even if the liquid material is supplied to the tank in conventional amounts, in other words, even if the vaporized gas is delivered at a conventional flow rate, changes in the pressure and temperature in the tank due to the supply are moderated. The liquid material vaporization apparatus can therefore be configured without a preheater that preheats the liquid material. It is thus possible to further increase the capacity of the tank.

In the gas generation mode, the opening degree of the first on-off valve can be set small (first opening degree) to allow the liquid material to flow into the tank only at a constant flow rate or less. It is therefore possible to restrain fluctuations in the pressure and temperature in the tank and to keep fluctuations in the delivery flow rate of the vaporized gas to conventional levels.

In the purge mode, on the other hand, the opening degree of the first on-off valve can be set large (second opening degree) to allow the purge gas to flow in large amounts. It is therefore possible to ensure the reliability and time shortening of a purge also in this mode as in the conventional case.

2

The liquid material vaporization apparatus according to [1], further including a float sensor that detects an amount of the liquid material stored in the tank, in which in the gas generation mode, opening and closing operations of the first on-off valve are controlled in response to a detection signal of the float sensor.

This configuration improves the reliability of detecting the amount of the liquid material stored in the tank.

3

The liquid material vaporization apparatus according to [1] or [2], in which the first opening degree is set in a changeable manner.

According to this configuration, the opening degree of the first on-off valve in the gas generation mode (first opening degree) can be set to an optimum opening degree depending on the type of the liquid material and the delivery flow rate of the vaporized gas.

4

An operation setting method of a liquid material vaporization apparatus including a tank, a supply path through which a liquid material is supplied to the tank, and a first on-off valve that is provided on the supply path, the operation setting method including:

causing the liquid material vaporization apparatus to operate such that, in a gas generation mode, the first on-off valve is set to a predetermined first opening degree, and the liquid material is supplied to the tank through the supply path via the first on-off valve and is vaporized in the tank; and

causing the liquid material vaporization apparatus to operate such that, in a purge mode, the first on-off valve is set to a second opening degree that is larger than the first opening degree, and a purge gas is introduced into the tank via the first on-off valve.

This configuration may also produce advantageous effects similar to those of [1] described above.

5

The operation setting method of the liquid material vaporization apparatus according to [4], in which the first opening degree is changed depending on at least a type of the liquid material.

According to this configuration, the opening degree of the first on-off valve in the gas generation mode (first opening degree) can be set to an optimum opening degree depending on the type of the liquid material.

According to the present invention, it is possible to increase the capacity of a tank to enjoy the benefit therefrom while securing conventional performance.

### BRIEF DESCRIPTION OF THE DRAWINGS

FIG. 1 is a schematic diagram schematically illustrating a configuration of a liquid material vaporization apparatus according to an embodiment of the present invention;

FIG. 2 is a schematic diagram schematically illustrating a configuration of a conventional liquid material vaporization apparatus; and

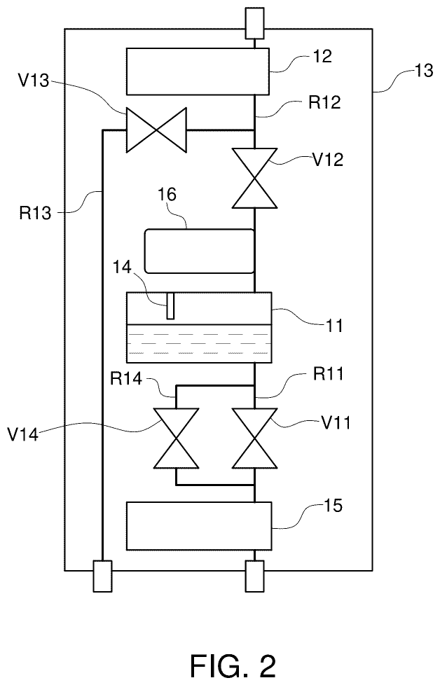

FIG. 3 is a graph showing that a delivery flow rate of a vaporized gas fluctuates at a timing of supplying a liquid material to a tank.

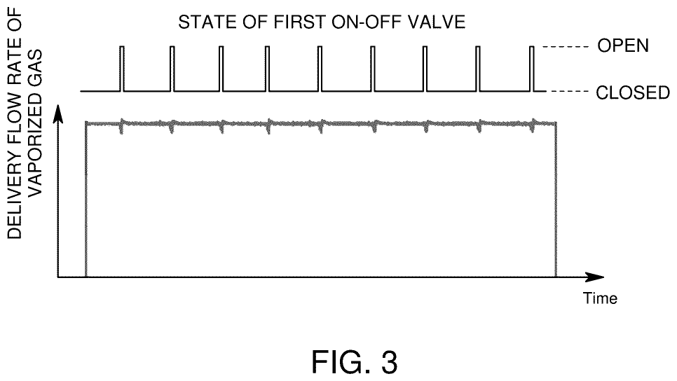

### DETAILED DESCRIPTION

Hereinafter, a liquid material vaporization apparatus according to an embodiment of the present invention will be described with reference to the drawings.

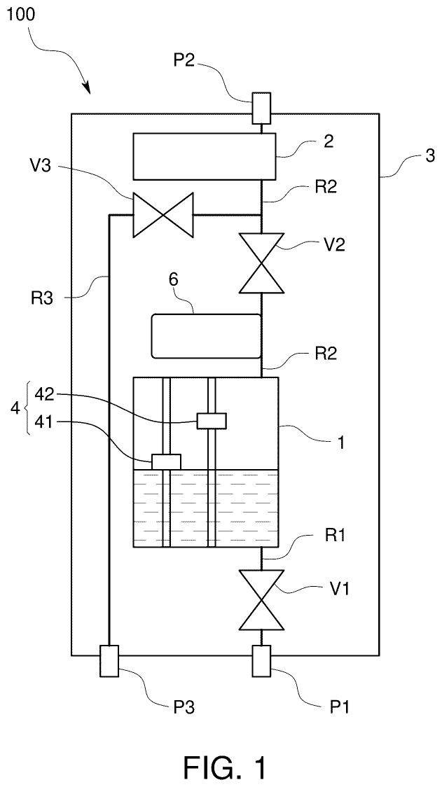

As illustrated in FIG. 1, a liquid material vaporization apparatus 100 of the present embodiment includes: a tank 1; a supply path R1 through which a liquid material is supplied to the tank 1; a heater (attached to the tank 1 and not illustrated) that heats the liquid material in the tank 1; a sensor mechanism 4 that is provided in the tank 1 and detects an amount (liquid level) of the liquid material; a gas delivery path R2 through which a vaporized gas generated from the liquid material by heat in the tank 1 is delivered; a flow rate controller 2 that performs FB control such that a flow rate of the vaporized gas flowing through the gas delivery path R2 is adjusted to a predetermined value; and a housing 3 that accommodates or holds these components.

The tank 1 is, for example, a hollow tank made of stainless steel or the like and having a rectangular parallelepiped shape.

The supply path R1 is formed of a tubular body or is formed by boring a hole in a block body. The supply path R1 has one end connected to a bottom surface of the tank 1, and the other end connected to a first port P1 of the housing 3. The first port P1 is connected to a liquid material source (not illustrated) or the like via a tube, a tubular body, or the like.

A single first on-off valve V1 is provided on the supply path R1. This first on-off valve V1 can exclusively control a flow of fluid flowing through the supply path R1. In this embodiment, the first on-off valve V1 is a pneumatic valve that can be opened and closed by remote operation; however, the first on-off valve V1 is not limited thereto.

In this embodiment, the sensor mechanism 4 includes two float sensors 41 and 42. Each of the float sensors 41 and 42 includes a float held so as to be movable up and down in a predetermined height range, and detects whether the float is in a floating state due to buoyancy exerted by the liquid material in the tank 1. In this embodiment, the float sensor 41 functions as a low-level sensor that detects whether the liquid material in the tank 1 is below a predetermined lower limit value. The float sensor 42 is higher in up-and-down movement range of the float than the float sensor 41, and functions as a high-level sensor that detects whether the liquid material in the tank 1 is above a predetermined upper limit value. In this embodiment, these two float sensors 41 and 42 can detect three states of the liquid material in the tank 1, that is, whether the liquid material is less than the lower limit value, is between the lower limit value and the upper limit value, and is more than the upper limit value.

The gas delivery path R2 is formed of a tubular body or is formed by boring a hole in a block body. The gas delivery path R2 has one end connected to an upper surface of the tank, and the other end connected to a second port P2 of the housing 3. The second port P2 is connected to a target device (not illustrated), such as a semiconductor process chamber, via a tube, a tubular body, or the like.

A second on-off valve V2 is provided on the gas delivery path R2. In this embodiment, the second on-off valve V2 is a pneumatic valve that can be opened and closed by remote operation; however, the second on-off valve V2 is not limited thereto.

The flow rate controller 2 is provided between the second on-off valve V2 and the second port P2 on the gas delivery path R2, and controls a mass flow rate of fluid flowing through the gas delivery path R2 in this embodiment. The flow rate controller 2 includes a flow rate control valve (not illustrated) and, for example, a thermal flow sensor (not illustrated). The flow rate controller 2 performs FB control on an opening degree of the flow rate control valve so as to bring a flow rate to be measured by the flow sensor close to a preset flow rate.

The liquid material vaporization apparatus further includes a purge gas introduction path R3 through which a purge gas is introduced into the flow rate controller 2. The purge gas introduction path R3 is formed of a tubular body or is formed by boring a hole in a block body. The purge gas introduction path R3 has one end connected in the middle of the gas delivery path R2, more specifically, between the second on-off valve V2 and the flow rate controller 2, and the other end connected to a third port P3 of the housing 3. The third port P3 is connected to a purge gas source (not illustrated) via a tube, a tubular body, or the like.

A third on-off valve V3 is provided on the purge gas introduction path R3. In this embodiment, the third on-off valve V3 is a pneumatic valve that can be opened and closed by remote operation; however, the third on-off valve V3 is not limited thereto.

Note that the purge gas introduction path R3 can be used in a case where a purge is performed on the flow rate controller 2 alone. At this time, the second on-off valve V2 is closed, the third on-off valve V3 is opened, and a purge gas introduced through the purge gas introduction path R3 is discharged out of the second port P2 via the flow rate controller 2.

In FIG. 1, reference numeral 6 denotes a pressure sensor that measures the pressure in the tank 1.

The first on-off valve V1 in this embodiment can switch between a closed state and an open state, and can also switch the opening degree in the open state between two opening degrees of a first opening degree and a second opening degree that is larger than the first opening degree. The closed state and the open state can be switched remotely based on an electric signal. The first opening degree and the second opening degree can be switched by manually operating an operation unit, such as a knob, provided on the body of the first on-off valve V1, or the like. An on-off valve that can remotely switch between the first opening degree and the second opening degree may be used.

Next, an operation of the liquid material vaporization apparatus 100 with the above configuration will be described.

The liquid material vaporization apparatus 100 operates in at least two modes, that is, a gas generation mode and a purge mode, as described above in “DESCRIPTION OF THE RELATED ART”.

In the gas generation mode, the second on-off valve V2 provided on the gas delivery path R2 is opened in response to a command signal from a control device (not illustrated), and a vaporized gas generated by heat from the heater in the tank 1 is guided to a target device, such as a semiconductor process chamber, through the gas delivery path R2 and the second port P2 while the flow rate is controlled to be constant by the flow rate controller 2. At this time, the third on-off valve V3 is closed.

When it is detected that the amount of the liquid material in the tank 1 falls below the lower limit value due to the delivery of the vaporized gas, the control device receives the detection signal, and transmits an open signal to the first on-off valve V1 provided on the supply path R1 to open the supply path R1. As a result, the liquid material is supplied to the tank 1. On the other hand, when it is detected that the amount of the liquid material in the tank 1 reaches or exceeds the upper limit value due to the supply of the liquid material, the control device receives the detection signal, and transmits a close signal to the first on-off valve V1 to close the supply path R1. As a result, the supply of the liquid material to the tank 1 is stopped.

The opening degree of the first on-off valve V1 in the open state in the gas generation mode is set to the first opening degree by manually operating the operation unit in advance.

In the purge mode, an internal control valve of the flow rate controller 2, the first on-off valve V1, and the second on-off valve V2 are all opened in response to a command signal from the control device.

The purge gas introduced from the first port P1 is introduced into the tank 1 through the supply path R1 and the first on-off valve V1, and then is discharged out of the second port P2 through the gas delivery path R2, the second on-off valve V2, and the flow rate controller 2.

The opening degree of the first on-off valve V1 in the open state in the purge mode is set to the second opening degree by manually operating the operation unit in advance.

According to the above configuration, the first on-off valve V1 has two functions, that is, a function of a conventional on-off valve for liquid material supply and a function of a conventional on-off valve for purge gas discharge. It is therefore possible to reduce the number of parts and increase the capacity of the tank 1 accordingly without changing the size of the housing 3.

As described in this embodiment, as a result, it is possible to use a float sensor and improve the reliability of detecting the liquid level in the tank.

In addition, since the capacity of the tank is increased, the liquid material can be stored in large amounts in the tank. Therefore, even if the liquid material is supplied to the tank 1 in conventional amounts, in other words, even if the vaporized gas is delivered at a conventional flow rate, changes in the pressure and temperature in the tank 1 due to the supply are moderated. The liquid material vaporization apparatus can therefore be configured without a preheater that preheats the liquid material. It is thus possible to increase the capacity of the tank.

In the gas generation mode, the opening degree of the first on-off valve V1 in the open state is small (first opening degree), which allows the liquid material to flow into the tank 1 only at a constant flow rate or less in supplying the liquid material to the tank 1. It is therefore possible to restrain fluctuations in the pressure and temperature in the tank 1 and to keep fluctuations in the delivery flow rate of the vaporized gas to conventional levels.

In the purge mode, on the other hand, the opening degree of the first on-off valve V1 is large (second opening degree). It is therefore possible to allow the purge gas to flow in large amounts, and also to ensure the reliability and time shortening of a purge.

Note that the present invention is not limited to the above embodiment.

For example, the first opening degree and the second opening degree may be changed depending on the type of the liquid material, the amount of the delivered vaporized gas, and the like.

The preheater is not provided in the above embodiment, but may be provided. Alternatively, a heater that heats the first on-off valve and/or the supply path may be provided in place of the preheater.

In addition, the present invention can be variously modified without departing from the spirit of the present invention.

### REFERENCE CHARACTERS LIST

100 liquid material vaporization apparatus
1 tank
R1 supply path
R2 gas delivery path
R3 purge gas introduction path
V1 first on-off valve

What is claimed is:

1. A liquid material vaporization apparatus comprising:
a tank;
a supply path through which a liquid material is supplied to the tank; and
a first on-off valve that is provided on the supply path,
the liquid material vaporization apparatus being configured to operate such that, in a gas generation mode, the liquid material is supplied to the tank through the supply path via the first on-off valve set to a predetermined first opening degree,
the liquid material vaporization apparatus being configured to operate such that, in a purge mode, a purge gas is introduced into the tank through the supply path via the first on-off valve set to a second opening degree that is larger than the first opening degree.

2. The liquid material vaporization apparatus according to claim 1, further comprising
a float sensor that detects an amount of the liquid material stored in the tank, wherein
in the gas generation mode, opening and closing operations of the first on-off valve are controlled in response to a detection signal of the float sensor.

3. The liquid material vaporization apparatus according to claim 1, wherein the first opening degree is set in a changeable manner.

4. An operation setting method of a liquid material vaporization apparatus including a tank, a supply path through which a liquid material is supplied to the tank, and a first on-off valve that is provided on the supply path, the operation setting method comprising:
causing the liquid material vaporization apparatus to operate such that, in a gas generation mode, the first on-off valve is set to a predetermined first opening degree, and the liquid material is supplied to the tank through the supply path via the first on-off valve and is vaporized in the tank; and
causing the liquid material vaporization apparatus to operate such that, in a purge mode, the first on-off valve is set to a second opening degree that is larger than the first opening degree, and a purge gas is introduced into the tank via the first on-off valve.

5. The operation setting method of the liquid material vaporization apparatus according to claim 4, wherein the first opening degree is changed depending on at least a type of the liquid material.
